(19) United States
(12) Patent Application Publication
(10) Pub. No.: US 2004/0171241 A1
(43) Pub. Date: Sep. 2, 2004

(54) Semiconductor device having gate electrode of polymetal gate structure processed by side nitriding in anmonia atmosphere

(76) Inventors: Eiji Kitamura, Tokyo (JP); Satoru Yamada, Tokyo (JP); Yoshiki Kato, Tokyo (JP); Kanta Saino, Tokyo (JP); Masayoshi Saito, Tokyo (JP); Shinpei Iijima, Tokyo (JP); Kiyonori Oyu, Tokyo (JP)

Correspondence Address: YOUNG & THOMPSON, 745 SOUTH 23RD STREET 2ND FLOOR, ARLINGTON, VA, 22202

(21) Appl. No.: 10/756,314

(22) Filed: Jan. 14, 2004

(30) Foreign Application Priority Data
Jan. 17, 2003 (JP) 2003-009490

(51) Int. Cl. H01L 21/3205; H01L 21/4763

(52) U.S. Cl. 438/592

(57) ABSTRACT

A semiconductor device has a reduced contact resistance between a tungsten film and a polysilicon layer and has a gate electrode prevented from being depleted for a reduced gate resistance. According to a method of fabricating such a semiconductor device, a semiconductor device having a gate electrode of a polymetal gate structure which comprises a three-layer structure having a tungsten (W) film, a tungsten nitride (WN) film, and a polysilicon (PolySi) layer, is manufactured by nitriding the sides of the gate electrode at a nitriding temperature ranging from 700° C. to 950° C. in an ammonia atmosphere after the gate electrode is formed and before side selective oxidization is performed on the gate electrode.

### BACKGROUND OF THE INVENTION

1. Field of the Invention

The present invention relates to a semiconductor device having a gate electrode of a polymetal gate structure which comprises a three-layer structure having a metal film, a barrier film, and a polysilicon layer, and a method of manufacturing such a semiconductor device.

2. Description of the Related Art

In recent years, efforts to reduce the size of semiconductor devices have resulted in a tendency for the MOSFETs in semiconductor devices to have a reduced gate length and an increased gate resistance. For the purpose of reducing the gate resistance, there has been proposed a polycide gate structure wherein a gate electrode has a two-layer structure made up of a metal silicide layer and polysilicon layer.

There has also been proposed a semiconductor device having a gate electrode of a polymetal gate structure for achieving a lower gate resistance than the polycide gate structure. The polymetal gate structure comprises a three-layer structure wherein a gate electrode is made up of a polysilicon layer, a barrier film, and a metal film. Specifically, the metal film comprises a tungsten film made of tungsten which is a metal having a high melting point, and the barrier film comprises a tungsten nitride film, so that the gate electrode is of a laminated layer structure comprising a tungsten film, a tungsten nitride film, and a polysilicon layer.

A process of manufacturing a conventional semiconductor device having a gate electrode of a polymetal structure will be described below with reference to FIGS. 1 through 9 of the accompanying drawings.

(1) First, as shown in FIG. 1 of the accompanying drawings, device-separating regions 10 are formed in a silicon substrate by a process such as an STI (Shallow Trench Isolation) process or the like, and a p-type impurity and an n-type impurity are injected respectively into NMOS and PMOS regions to form a P well and an N well.

(2) Then, as shown in FIG. 2 of the accompanying drawings, gate insulating film 21, silicon layer 22, barrier film 23, and tungsten film 24 are successively formed on the silicon substrate, and mask nitride film 25 serving as an etching mask for forming a gate is deposited on tungsten film 24. The process of forming these films and layers will be described in detail below.

First, gate oxidization is performed to form gate insulating film 21. Then, silicon is deposited by an LPCVD (Low Pressure Chemical Vapor Deposition) process to form polysilicon layer 22. Polysilicon layer 22 is formed of n-type polysilicon or p-type polysilicon, for example. If a dual gate is to be employed, then the NMOS region is formed of n-type polysilicon, and the PMOS region is formed of p-type polysilicon. For example, non-doped silicon is deposited, and an n-type impurity and a p-type impurity are injected using an injection mask. To activate these impurities, RTA (Rapid Thermal Annealing) is performed 950° C. for 10 seconds in an N₂ atmosphere. Phosphorus or arsenic is introduced into the NMOS region by way of ion implantation, and boron or indium is introduced into the PMOS region by way of ion implantation at 10 keV and 3×10¹⁵/cm⁻².

Then, barrier film 23 is formed of tungsten nitride, and tungsten film 24 is deposited on barrier film 23 by sputtering. Barrier film 23 has a thickness of 10 nm, and tungsten film 24 has a thickness of 80 nm, for example.

Finally, silicon nitride is deposited as mask nitride film 25 on tungsten film 24 by plasma CVD. Mask nitride film 25 has a thickness of 180 nm, for example.

(3) Then, as shown in FIG. 3 of the accompanying drawings, a photoresist 31 is patterned to a desired gate pattern on mask nitride film 25.

(4) Then, as shown in FIG. 4 of the accompanying drawings, using photoresist 31 as a mask, mask nitride film 25 is etched. After photoresist 31 is removed, tungsten film 24, barrier film 23, and polysilicon layer 22 are etched using mask nitride film 25 as a mask, forming gate electrode 41.

Thereafter, the assembly is subjected to side selective oxidization to oxidize the sides of polysilicon layer 22 and the silicon of the silicon substrate. The oxidization is performed at 750° C. for 105 minutes in an H₂O/H₂/N₂ atmosphere such that tungsten film 24 on the polymetal gate is not oxidized and polysilicon layer 22 is oxidized.

The selective oxidization is carried out in order to increase the thickness of the gate oxide film on the gate ends to reduce a leakage current between polysilicon layer 22 and the silicon substrate, by oxidizing polysilicon layer 22 at the gate ends and the silicon substrate. The selective oxidization is also considered to serve the purpose of recovering from damage caused by the gate etching.

(5) As shown in FIG. 5 of the accompanying drawings, extension regions 52 and pocket injection layers 51 are formed in the NMOS region and the PMOS region using an injection mask. An n-type impurity is injected into extension region 52 in the NMOS region, and a p-type impurity is injected into extension region 52 in the PMOS region. A p-type impurity is injected into pocket injection layer 51 in the NMOS region, and an n-type impurity is injected into pocket injection layer 51 in the PMOS region.

(6) Then, as shown in FIG. 6 of the accompanying drawings, a nitride film is deposited on the entire surface formed so far by CVD, and then etched back by post-anisotropic etching, forming spacers 61 on the gate sides.

(7) Then, as shown in FIG. 7 of the accompanying drawings, source/drain regions 71, 72 are formed in the NMOS region and the PMOS region using an injection mask. An n-type impurity is injected into source/drain regions 71, 72 in the NMOS region, and a p-type impurity is injected into source/drain regions 71, 72 in the PMOS region.

(8) Then, as shown in FIG. 8 of the accompanying drawings, the entire surface formed so far is covered with an insulating film such as an oxide film or the like, which is planarized by CMP or the like. The insulating film serves as interlayer film 81 between the silicon substrate and gate electrode 41, and upper interconnections.

(9) Finally, as shown in FIG. 9 of the accompanying drawings, contact holes 92 are formed in the source and drain regions of the silicon substrate and gate electrode 41 by photolithography and etching, and a conductive film is embedded in contact holes 92. Then, interconnections or electrode pads 91 are patterned on the conductive film.

The conventional semiconductor device described above has suffered a problem in that since the side selective oxidization is performed while polysilicon layer 22 is exposed, a contact resistance between tungsten film 24 and polysilicon layer 22 is increased, and the gate resistance cannot be reduced.

Conventional processes for reducing the gate resistance by performing side nitridation on the gate electrode by way of RTA in a nitrogen (N₂) atmosphere prior to the side selective oxidization are disclosed in the following documents 1, 2, for example:

Document 1: Japanese laid-open patent publication No. 2001-326348; and

Document 2: Japanese laid-open patent publication No. 2002-16248.

The above conventional processes are based on the idea that when the sides of polysilicon layer 22 are excessively oxidized to reduce the gate length, the area of contact between polysilicon layer 22 and tungsten film 24 is reduced, increasing the contact resistance, resulting in an increase in the contact resistance due to the side selective oxidization. According to the conventional processes of fabricating semiconductor devices, a nitride film is provided on the gate sides to form silicon nitride films on the sides of polysilicon layer 22. Since the silicon nitride films serve as oxidization prevention films, according to the conventional processes, when the side selective oxidization is effected on the gate electrode, the sides of polysilicon layer 22 are prevented from being excessively oxidized to prevent the contact resistance from being increased, thus suppressing an increase in the gate resistance.

However, the inventors of the present application have found that the contact resistance between tungsten film 24 and polysilicon layer 22 cannot sufficiently be reduced simply by providing a silicon nitride film functioning as an oxidization prevention film on the sides of the gate electrode to maintain the area of contact between tungsten film 24 and polysilicon layer 22.

There has been a demand for a process of fabricating semiconductor devices to make the gate resistance smaller than the above conventional processes of fabricating semiconductor devices. Furthermore, for reducing the gate resistance, it is necessary not only to lower the contact resistance between tungsten film 24 and polysilicon layer 22, but also to prevent the depletion of the gate electrode to keep the impurity concentration at a certain high level.

### SUMMARY OF THE INVENTION

It is an object of the present invention to provide a semiconductor device having a reduced contact resistance between a tungsten film and a polysilicon layer and having a gate electrode prevented from being depleted for a reduced gate resistance, and a method of fabricating such a semiconductor device.

To achieve the above object, there is provided in accordance with an aspect of the present invention a method of fabricating a semiconductor device having a gate electrode of a polymetal gate structure which comprises a three-layer structure having a metal film, a barrier film, and a polysilicon layer, comprising the steps of successively forming a gate insulating film, a polysilicon layer, a barrier film, and a metal film on a semiconductor substrate, etching the metal film, the barrier film, and the polysilicon layer to form a gate electrode, effecting side nitridation on the gate electrode at a nitriding temperature ranging from 700° C. to 950° C. in an ammonia atmosphere, and effecting side selective oxidization to oxidize the polysilicon layer and silicon in the semiconductor substrate without oxidizing the metal film.

According to the present invention, after the gate electrode is formed and before side selective oxidization is effected on the gate electrode, the sides of the gate electrode are nitrided at a low nitriding temperature ranging from 700° C. to 950° C. in an ammonia atmosphere. Therefore, a silicon nitride film is formed on the sides of the polysilicon layer without accelerating outward diffusion of impurities in the polysilicon layer. The silicon nitride film thus formed is effective to reduce an oxidized amount of the polysilicon layer and also to reduce an injected amount of interstitial Si atoms, thereby suppressing rapid diffusion of the impurities. Therefore, the impurity concentration in a tungsten interface of the polysilicon layer is kept at a high level, reducing the contact resistance between the metal film and the polysilicon layer.

Upon side selective oxidization, an oxide nitride film is formed on the sides of the polysilicon layer. The impurities in the polysilicon layer are diffused outwardly in subsequent heat treatment processes. The impurity concentration in the tungsten interface of the polysilicon layer is kept at a high level, reducing the contact resistance between the metal film and the polysilicon layer.

Since the impurities in the polysilicon layer are diffused outwardly in subsequent heat treatment processes, the impurity concentration in a gate oxide film interface of the polysilicon layer is also kept at a high level, suppressing the depletion of the gate electrode.

Because the contact resistance between the metal film and the polysilicon layer is reduced and the depletion of the gate electrode is suppressed, the resistance of the gate electrode is reduced.

According to another aspect of the present invention, there is also provided a method of fabricating a semiconductor device having a gate electrode of a polymetal gate structure which comprises a three-layer structure having a metal film, a barrier film, and a polysilicon layer, comprising the steps of successively forming a gate insulating film, a polysilicon layer, a barrier film, and a metal film on a semiconductor substrate, etching the metal film, the barrier film, and the polysilicon layer to form a gate electrode, effecting side nitridation on the gate electrode by way of plasma nitridation, and effecting side selective oxidization to oxidize the polysilicon layer and silicon in the semiconductor substrate without oxidizing the metal film.

According to the other aspect of the present invention, since the sides of the gate electrode are nitrided by plasma nitridation, the method does not suppress the oxidization of the semiconductor substrate by nitriding the semiconductor substrate. The method according to the other aspect of the present invention offers the same advantages as those offered by the method which nitrides the gate electrodes by way of RTS in the ammonia atmosphere.

The metal film may comprise a tungsten film, and the barrier film may comprise a tungsten nitride film.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a cross-sectional view showing steps of a process of fabricating a semiconductor device of polymetal gate structure;

FIG. 2 is a cross-sectional view showing steps of the process of fabricating a semiconductor device of polymetal gate structure;

FIG. 3 is a cross-sectional view showing steps of the process of fabricating a semiconductor device of polymetal gate structure;

FIG. 4 is a cross-sectional view showing steps of the process of fabricating a semiconductor device of polymetal gate structure;

FIG. 5 is a cross-sectional view showing steps of the process of fabricating a semiconductor device of polymetal gate structure;

FIG. 6 is a cross-sectional view showing steps of the process of fabricating a semiconductor device of polymetal gate structure;

FIG. 7 is a cross-sectional view showing steps of the process of fabricating a semiconductor device of polymetal gate structure;

FIG. 8 is a cross-sectional view showing steps of the process of fabricating a semiconductor device of polymetal gate structure;

FIG. 9 is a cross-sectional view showing steps of the process of fabricating a semiconductor device of polymetal gate structure;

FIG. 10 is a diagram showing a comparison of effects produced when RTA was performed in a nitrogen atmosphere and when RTA was performed in an ammonia atmosphere, on nitridation at the same side nitrogen concentration;

FIG. 11 is a diagram showing a comparison of effects produced when RTA was performed in a nitrogen atmosphere and when RTA was performed in an ammonia atmosphere, on side nitridation at the same nitriding temperature;

FIG. 12 is a diagram showing a comparison of a process of fabricating a semiconductor device according to a first embodiment of the present invention and a conventional process of fabricating a semiconductor device, from the step of gate etching to the step of gate side oxidization;

FIG. 13 is a diagram showing how the contact resistance between a tungsten film and a polysilicon layer changes when the side nitriding temperature changes;

FIG. 14 is a diagram showing how the donor concentration in an interface between a polysilicon layer and a gate oxide film changes when the side nitriding temperature changes;

FIG. 15 is a diagram showing how the donor/acceptor concentration in an interface between a tungsten film and a polysilicon layer and the dopant concentration in an interface between a polysilicon layer and a gate oxide film change depending on the side nitriding temperature;

FIG. 16 is a diagram showing the profile of an impurity concentration in a polysilicon layer at the time the side nitriding temperature changes;

FIG. 17 is a diagram showing the impurity concentration dependency of a contact resistance;

FIG. 18 is a diagram showing a lower limit for nitriding conditions;

FIG. 19 is a diagram showing an upper limit for nitriding conditions;

FIG. 20 is a diagram showing the nitriding temperature dependency of a nitrogen concentration; and

FIG. 21 is a diagram showing the relationship between a ratio of re-oxidized amounts and a nitrogen peak concentration when gate side nitridation was performed by plasma nitridation according to a second embodiment of the present invention and when gate side nitridation was performed by RTA in an ammonia atmosphere according to the first embodiment of the present invention.

### DETAILED DESCRIPTION OF THE PREFERRED EMBODIMENTS

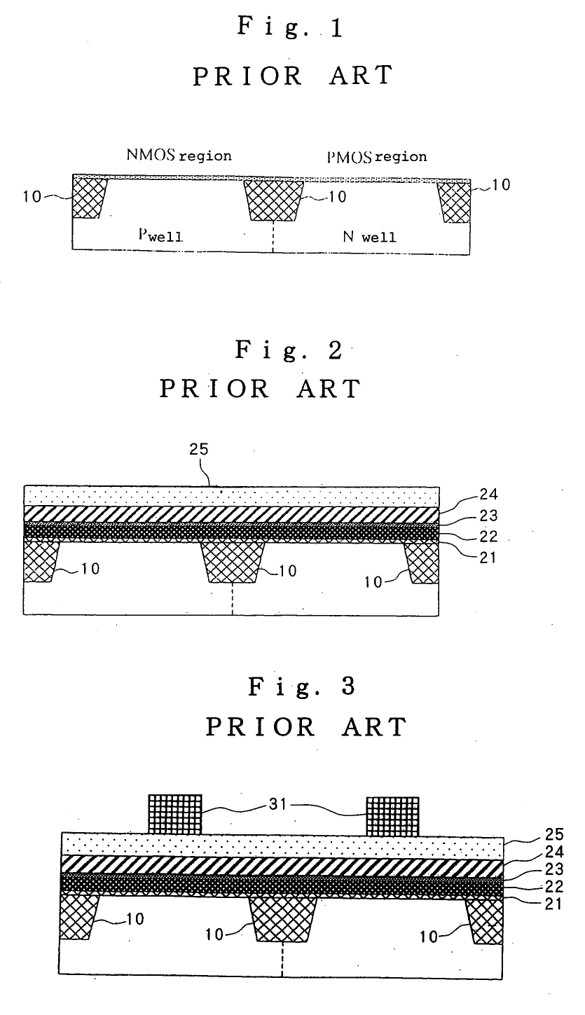

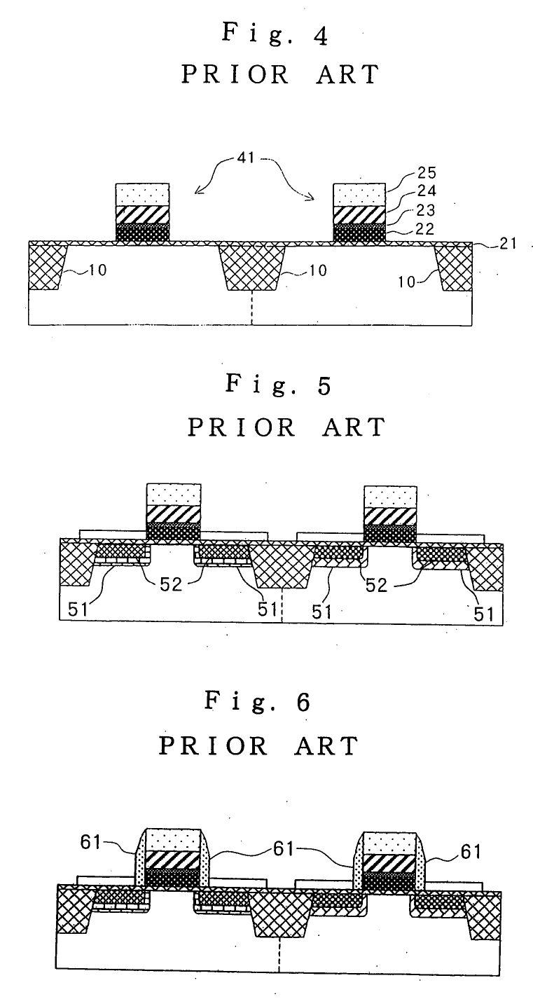

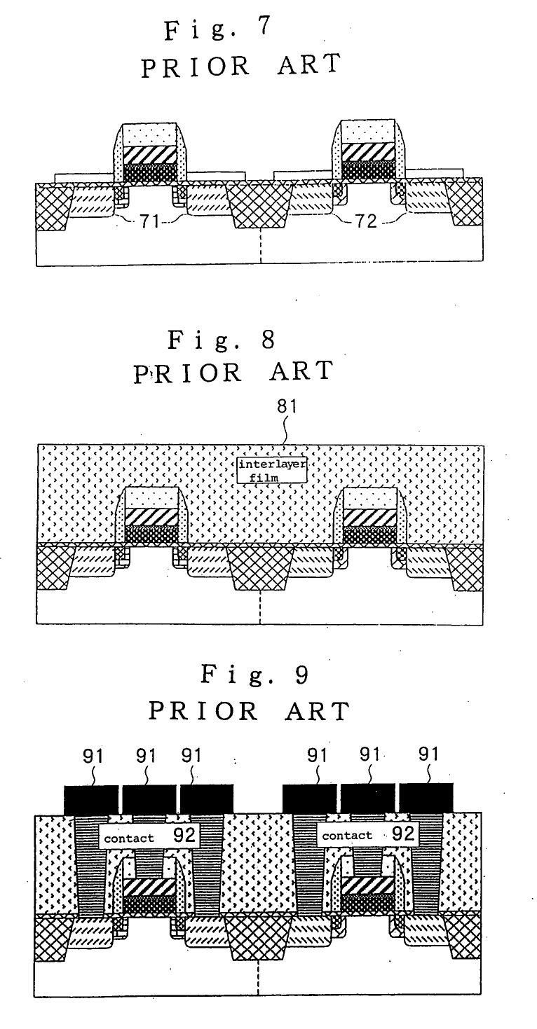

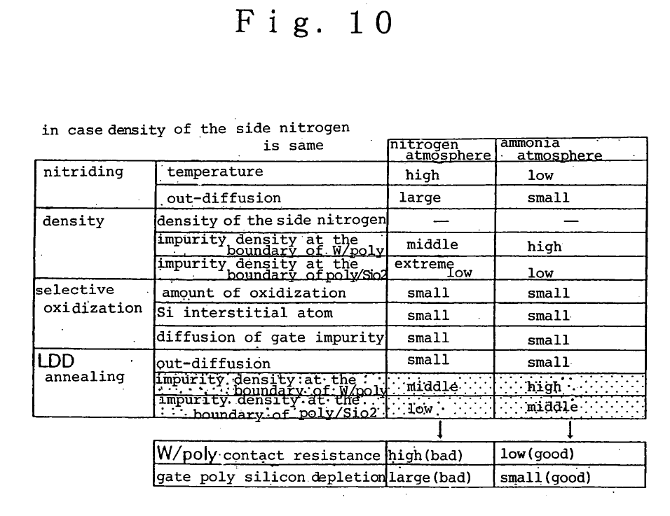

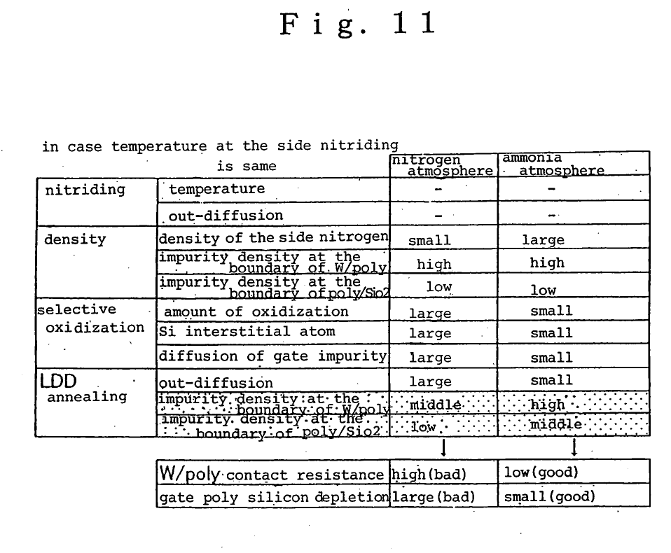

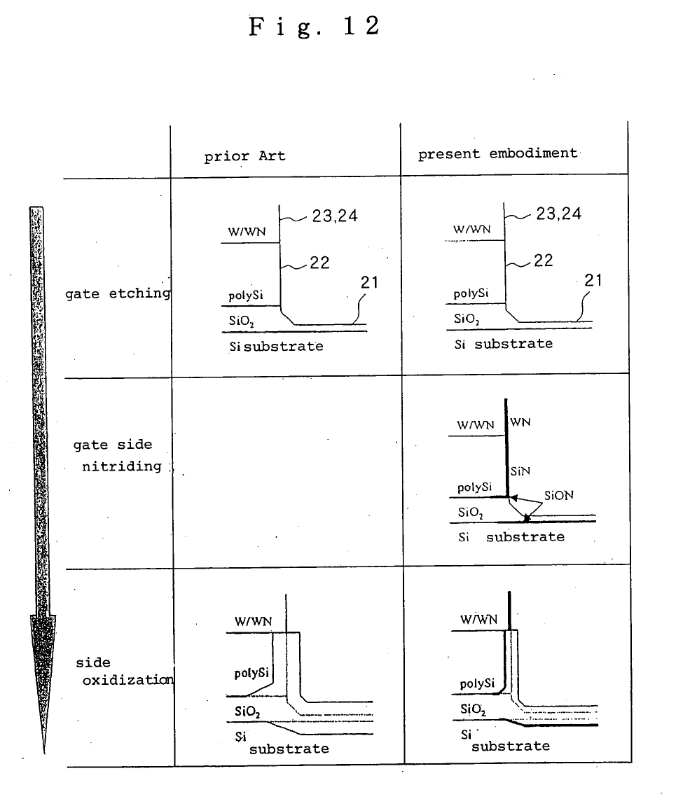

Preferred embodiments of the present invention will be described in detail below with reference to the drawings. FIGS. 1 through 9 are illustrative of a conventional process of fabricating semiconductor devices of polymetal gate structure. The embodiments of the present invention will be described below using the reference numerals shown in FIGS. 1 through 9.

1st Embodiment:

A method of fabricating a semiconductor device according to a first embodiment of the present invention will be described below.

The inventors of the present application has determined that when side selective oxidization is performed on a MOSFET of polymetal gate structure while polysilicon layer 22 is exposed, the contact resistance between tungsten film 24 and polysilicon layer 22 is increased because an impurity profile varies due to the following two phenomena:

The two phenomena includes a phenomenon in which an impurity in polysilicon layer 22 is diffused outwardly from the sides of the gate electrode and a phenomenon in which an impurity is diffused at an increased rate to lower the impurity concentration in an upper portion of polysilicon layer 22 because of an injection of interstitial Si atoms which occurs when polysilicon layer 22 of the gate electrode is oxidized. In view of these phenomena, the inventors of the present application has invented a structure and a process for suppressing the outward diffusion of the impurity in polysilicon layer 22 and the injection of interstitial Si atoms upon oxidization thereby to prevent the impurity profile for the purpose of lowering the contact resistance between tungsten film 24 and polysilicon layer 22.

The inventors of the present application has also determined that the gate resistance is increased by side selective oxidization on the gate electrode because the gate electrode tends to be depleted.

Details reasons why the gate resistance is increased by side selective oxidization on the gate electrode with polysilicon layer 22 being exposed will be described below.

First, the contact resistance between tungsten film 24 and polysilicon layer 22 is increased for the following two reasons:

(1) If the gate electrode is oxidized while polysilicon layer 22 of gate electrode 41 is exposed, the oxidized amount increases. If oxidized amount increases, then the amount of interstitial Si atoms injected into silicon layer 22 also increases. Therefore, impurities such as phosphorus and boron in polysilicon layer 22 which occur while the gate electrode is being oxidized or heated after being oxidized are diffused at an increased rate, resulting in a reduction in the impurity concentration in a tungsten interface.

(2) If the sides of polysilicon layer 22 are exposed, then the impurities in polysilicon layer 22 tend to be diffused outwardly in subsequent heat treatment processes, with the result that the impurity concentration in a tungsten interface in polysilicon layer 22 is lowered.

The gate electrode tends to be depleted for the following reason:

If the sides of polysilicon layer 22 are exposed, then the impurities in polysilicon layer 22 tend to be diffused outwardly in subsequent heat treatment processes, with the result that the impurity concentration is lowered not only in the tungsten interface, but also in a gate oxide film interface.

If the above phenomena are to be suppressed to prevent the gate resistance from being increased, then as disclosed in the above documents 1, 2, it may be proposed to nitride the sides of polysilicon layer 22 to form a nitride film on the sides of polysilicon layer 22 before side selective oxidization is effected on the gate electrode. For reducing the outward diffusion, it is preferable to perform stronger nitridation to form a thicker nitride film. Stronger nitridation can be achieved at a higher temperature. However, nitridation at a higher temperature accelerates the outward diffusion upon nitridation, resulting in a reduction in the impurity concentration in polysilicon layer 22. Therefore, it is necessary to employ a process for performing stronger nitridation without processing the assembly at a higher temperature.

The LPCVD is effective to perform nitridation at a desired concentration without processing the assembly at a higher temperature. However, the LPCVD cannot be used because it would nitride not only the sides of the gate electrode, but also the silicon substrate.

The process of nitriding the assembly in the N₂ atmosphere as disclosed in the above documents 1, 2 cannot perform stronger nitridation unless the temperature is increased. However, as described above, since nitridation at a higher temperature accelerates the outward diffusion, nitriding the assembly in the N₂ atmosphere fails to sufficiently suppress variations in the impurity profile. For example, if a desired nitride film is to be obtained by nitriding the assembly in the N₂ atmosphere, then the temperature for nitridation needs to be as high as about 1200° C. Nitriding the assembly at such a high temperature would cause outward diffusion upon nitridation of the gate sides, inviting a reduction in the impurity concentration and failing to achieve a desired impurity profile.

In the method of fabricating a semiconductor device according to the first embodiment of the present invention, after gate electrode 41 is formed and before the sides of the gate are subjected to side selective oxidization, the sides of gate electrode 41 are nitrided in an ammonia (NH₃) atmosphere. In this step, the sides of the gate electrode and the silicon substrate are nitrided. The ammonia atmosphere is made up of 100% of NH₃. The nitriding temperature is 1000° C. or lower.

A comparison of effects produced when RTA was performed in a nitrogen atmosphere and when RTA was performed in an ammonia atmosphere will be described below with reference to FIGS. 10 and 11. FIG. 10 shows the effects produced when the assembly was nitrided at the same side nitrogen concentration, and FIG. 11 shows the effects produced the assembly was subjected to side nitridation at the same nitriding temperature.

It can be seen from FIG. 10 that if the assembly is nitrided at the same side nitrogen concentration in a nitrogen atmosphere, then the nitriding temperature is higher, resulting in greater outward diffusion, than if the assembly is nitrided in an ammonia atmosphere. If the assembly is nitrided in a nitrogen atmosphere, therefore, the impurity concentration is lowered and the contact resistance between tungsten film 24 and polysilicon layer 22 is increased, depleting polysilicon 22. As a result, the gate resistance cannot be held to a low value.

It can be seen from FIG. 11 that if the assembly is nitrided for side nitridation at the same nitriding temperature, then the nitrogen concentration of the formed silicon nitride is lower than if the assembly is nitrided in an ammonia atmosphere. Therefore, with the silicon nitride produced by nitriding the assembly in the nitrogen atmosphere, the oxidized amount of polysilicon layer 22 upon selective oxidization cannot be suppressed, and the injection of interstitial Si atoms in polysilicon layer 22 cannot sufficiently be suppressed. Therefore, the contact resistance between tungsten film 24 and polysilicon layer 22 is increased, depleting polysilicon 22. As a result, the gate resistance cannot be held to a low value.

A comparison of a process of fabricating a semiconductor device according to a first embodiment of the present invention and a conventional process of fabricating a semiconductor device without gate side nitridation, from the step of gate etching to the step of gate side oxidization, will be described below with reference to FIG. 12.

It can be understood from FIG. 12 that at the time the gate etching is finished, there is no difference between the conventional fabricating process and the fabricating process according to the present embodiment. In the fabricating process according to the present embodiment, gate side nitridation is performed after the gate etching to form tungsten nitride (WN) on the sides of tungsten film 24 and silicon nitride (SiN) on the sides of polysilicon layer 22. Furthermore, silicon nitride (SiN) or silicon oxide nitride (SiON) is formed on part of an interface between gate insulating film 21 and polysilicon layer 22 and an interface between gate insulating film 21 and the silicon substrate.

When the gate electrode is subjected to side selective oxidation after the gate side nitridation, an oxide nitride film is formed on the sides of polysilicon layer 22. The nitrogen peak concentration in the oxide nitride film is 10 (atom %) or higher. The oxide nitride film has a film thickness of about 3 nm.

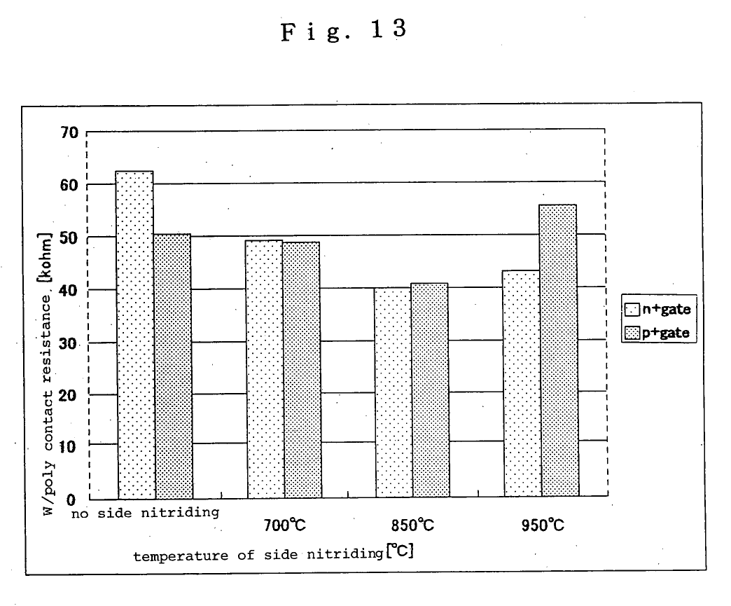

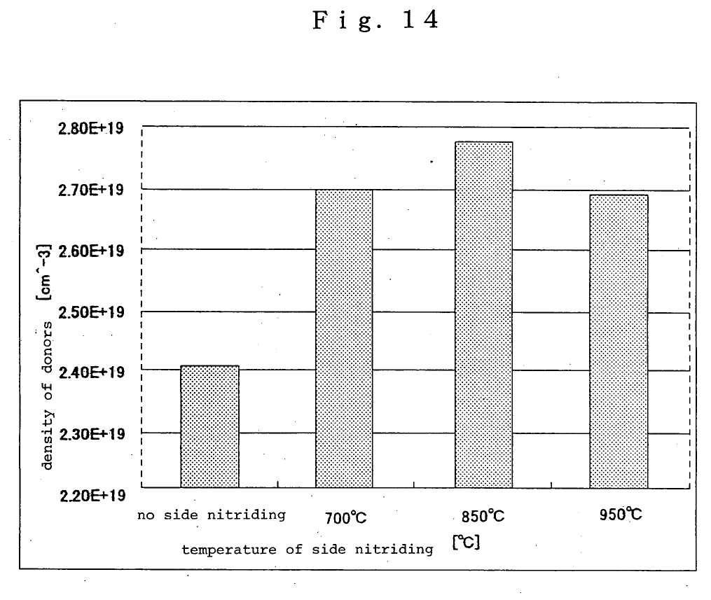

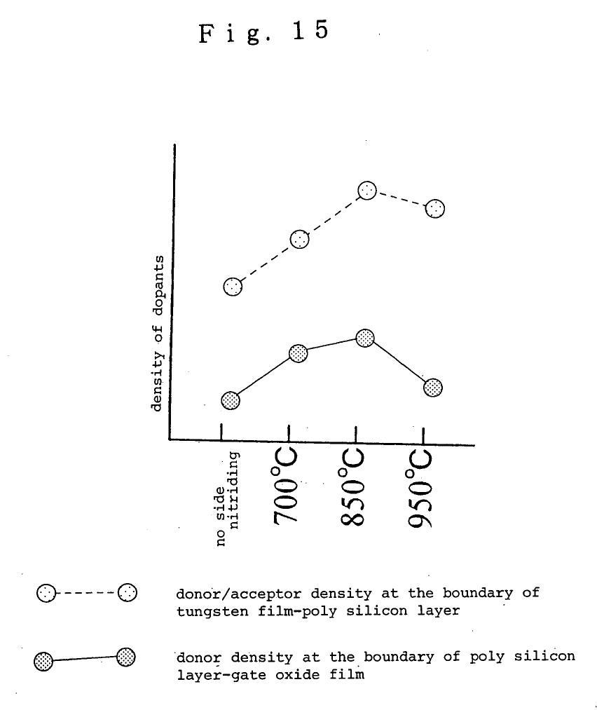

The characteristics of the semiconductor device thus fabricated according to the present embodiment will be described below with reference to FIGS. 13 through 19.

FIG. 13 shows how the contact resistance between tungsten film 24 and polysilicon layer 22 changes when the side nitriding temperature changes. FIG. 14 shows how the donor concentration in an interface between polysilicon layer 22 and gate oxide film 21 changes when the side nitriding temperature changes.

FIG. 15 shows how the donor/acceptor concentration in an interface between tungsten film 24 and polysilicon layer 22 and the dopant concentration in an interface between polysilicon layer 22 and gate oxide film 21 change depending on the side nitriding temperature. In FIG. 15, the donor/acceptor concentration in the interface between tungsten film 24 and polysilicon layer 22 is estimated from the values of the contact resistance shown in FIG. 13, and the dopant concentration in the interface between polysilicon layer 22 and gate oxide film 21 is estimated from the measured C-V results.

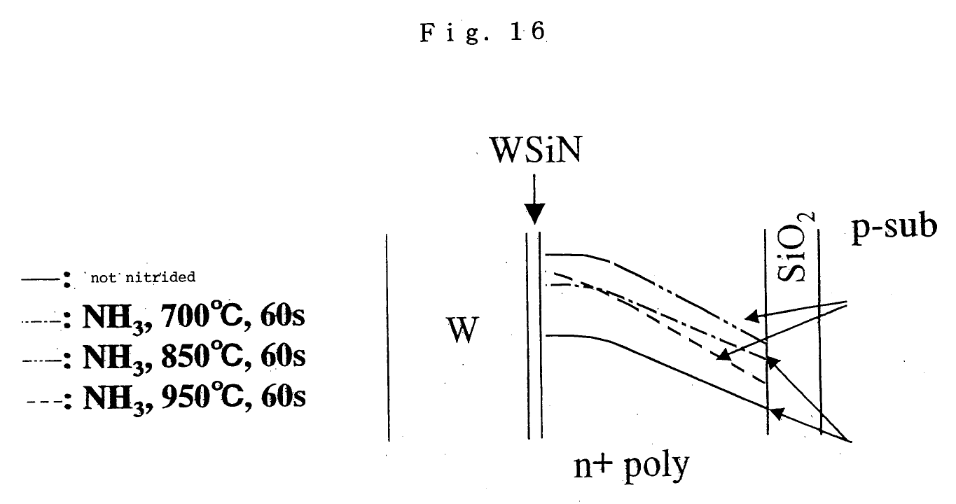

FIG. 16 shows the profile of an impurity concentration in the polysilicon layer at the time the side nitriding temperature changes. A review of FIG. 16 indicates that if the nitriding temperature is 850° C. and 950° C., the profile of the impurity concentration has a sharp gradient, and the diffusion of the dopant is slow. It can also be seen from FIG. 16 that if the nitriding temperature is 700° C. and if no gate side nitridation is performed, the profile of the impurity concentration has a gradual gradient, and diffusion of the dopant is fast.

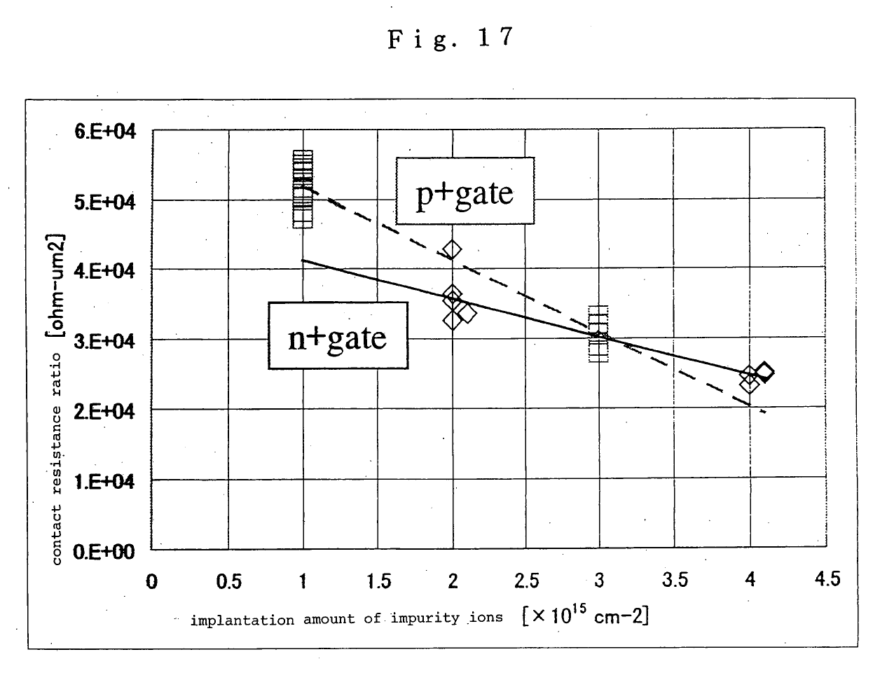

FIG. 17 shows the impurity concentration dependency of the contact resistance between tungsten film 24 and polysilicon layer 22. It will be understood from FIG. 17 that the constant resistivity is lower as the amount of injected impurity ions is larger.

The reasons why the contact resistance between tungsten film 24 and polysilicon layer 22 can be made smaller by the method of fabricating a semiconductor device according to the present embodiment than by the conventional process of fabricating a semiconductor device without gate side nitridation, will be described below.

The contact resistance between tungsten film 24 and polysilicon layer 22 can be reduced for the following two reasons:

(1) If polysilicon layer 22 covered with silicon nitride is oxidized, the oxidized amount is smaller than if polysilicon layer 22 is not covered with silicon nitride. Since the oxidized amount is reduced, the amount of amount of interstitial Si atoms injected into silicon layer 22 is also reduced. Therefore, the rapid diffusion of impurities such as phosphorus and boron in polysilicon layer 22 which occur while the gate electrode is being oxidized or heated after being oxidized is suppressed. The rapid diffusion of the dopant is suppressed because as the nitrogen concentration is higher, the amount of interstitial Si atoms injected upon gate side oxidization is smaller.

In as much as the impurities in polysilicon layer 22 are introduced by low-energy ion implantation, the impurity concentration in the tungsten interface is higher than the average concentration in polysilicon layer 22. Therefore, the impurity concentration in the tungsten interface is kept at a high level when the diffusion is suppressed. As shown in FIG. 15, impurity concentration in the tungsten interface is increased by gate side nitridation. As a result, as shown in FIG. 13, the contact resistance between tungsten film 24 and polysilicon layer 22 can be reduced by performing gate side nitridation.

(2) An oxide nitride film is formed on the sides of polysilicon layer 22 by gate side nitridation. The oxide nitride film is effective to suppress outward diffusion of the impurities in polysilicon layer 22 in subsequent heat treatment processes. As a result, as shown in FIG. 15, the impurity concentration in the tungsten interface is kept at a high level. The contact resistance between tungsten film 24 and polysilicon layer 22 depends on the impurity concentration in polysilicon layer 22. As the impurity concentration is higher, the resistance is lower. As a consequence, as shown in FIG. 13, the contact resistance between tungsten film 24 and polysilicon layer 22 can be reduced by performing gate side nitridation.

The method of fabricating a semiconductor device according to the present embodiment is able to improve the depletion of the gate electrode compared with the conventional process of fabricating a semiconductor device without gate side nitridation. The reasons why the depletion of the gate electrode is improved are as follows:

As described above, when gate side oxidization is performed, an oxide nitride film is formed on the sides of polysilicon layer 22, and the oxide nitride film suppresses outward diffusion of the impurities in polysilicon layer 22 in subsequent heat treatment processes. As a result, as shown in FIGS. 14 and 15, the impurity concentration is kept at a high level not only in the tungsten interface, but also in the gate oxide film interface. Therefore, the depletion of the gate electrode is improved.

If the method of fabricating a semiconductor device according to the present embodiment is applied to a p+ gate electrode of dual polymetal gate structure, then the penetration of boron into the gate oxide film is suppressed, in addition to achieving the above advantages. The penetration of boron into the gate oxide film is suppressed for the following reasons:

It is known that if the assembly is heated in a hydrogen atmosphere, the hydrogen accelerates the diffusion of boron in the silicon oxide film. Therefore, if the assembly is oxidized while the polymetal gate is exposed, the polysilicon layer is exposed to the hydrogen atmosphere. In a P-type polysilicon gate with boron introduced therein, the probability that the boron penetrates the gate oxide film and reaches the silicon substrate is high. If the boron reaches the silicon substrate, it causes adverse effects such as variations in the threshold voltage of MOS transistors. However, if an oxide nitride film is formed on the sides of the polysilicon layer, then the oxide nitride film suppresses the diffusion of hydrogen into the polysilicon layer, resulting in a reduction in the probability that the boron penetrates the gate oxide film and reaches the silicon substrate.

Secondary advantages produced by the gate side nitridation are the improvement of control characteristics for a under-gate birds beak upon side selective oxidization, and the improvement of pause/refresh characteristics.

If side selective oxidization is performed without gate side nitridation, then since the assembly is oxidized with nothing or a thin oxide film on the sides of polysilicon layer 22, polysilicon layer 22 at the gate edges, and the silicon substrate, polysilicon layer 22 at the gate edges and the silicon substrate tend to be excessively oxidized. Therefore, it is difficult to control the under-gate birds beak upon side selective oxidization.

If gate side nitridation is performed prior to side selective oxidization, then since the assembly is oxidized with an oxide nitride film on the sides of polysilicon layer 22, polysilicon layer 22 at the gate edges, and the silicon substrate, polysilicon layer 22 at the gate edges and the silicon substrate are prevented from being excessively oxidized.

The pause/refresh characteristics can be improved for the following reasons:

If no gate side nitridation is performed, then subsequent steps are carried out with tungsten film 24 exposed on the sides of gate electrode 41. Therefore, the metal material (tungsten) is scattered in an increased quantity in subsequent heat treatment processes, and the amount of metal implanted into the silicon substrate is increased by the knock-on upon ion implantation. Of the metal implanted into the silicon substrate, the metal which is present in the depletion layer increases a pn-junction leakage current, resulting in degraded pause/refresh characteristics.

If gate side nitridation is performed prior to side selective oxidization, then an oxide nitride film is formed on the sides of polysilicon layer 22 of gate electrode 41. At the same time, a nitride is formed on the sides of the metal material of tungsten film 24 above polysilicon layer 22. The nitride thus formed is effective to reduce the scattered amount of the metal material in subsequent heat treatment processes. If the scattered amount of the metal material is reduced, then the amount of metal implanted into the silicon substrate by the knock-on upon ion implantation is also reduced. Of the metal implanted into the silicon substrate, the metal which is present in the depletion layer increases a pn-junction leakage current. Since this drawback is reduced, the pn-junction leakage current is reduced, improving the pause/refresh characteristics.

The method of fabricating a semiconductor device according the present embodiment offers the various advantages described above. However, simply nitriding polysilicon layer 22 of gate electrode 41 is not effective, but there are certain nitriding conditions for nitriding the gate sides and certain limitative conditions for the oxide nitride film on polysilicon layer 22 for achieving the above advantages.

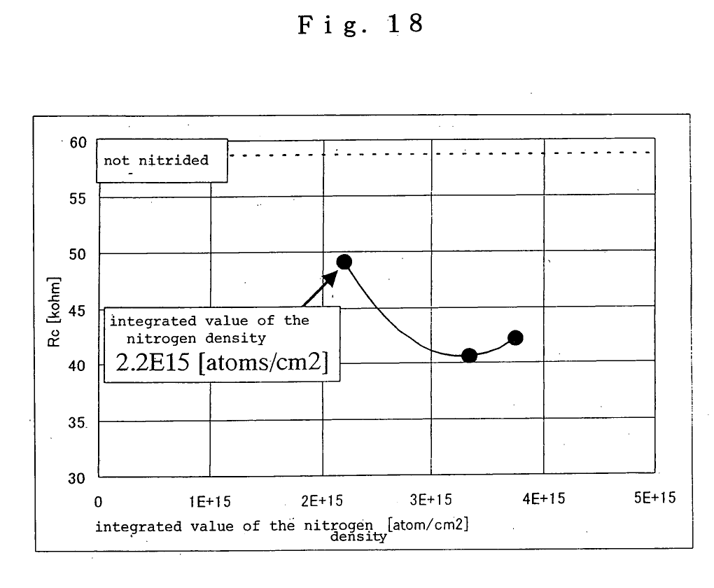

First, the nitrogen concentration in the oxide nitride film on the sides of polysilicon layer 22 of gate electrode 41 is limited under the following conditions. The nitrogen concentration in the oxide nitride film which is required to suppress the outward diffusion of the impurities in polysilicon layer 22 of gate electrode 41 and the injection of interstitial Si atoms upon oxidization depends not only on nitriding conditions, but also on oxidizing conditions. Therefore, a lower limit for the nitrogen concentration is determined by the nitrogen concentration after oxidization. It can be seen from FIG. 18 that the lower limit for an integrated value of the nitrogen concentration should preferably be 2.0×10¹⁵ (atoms/cm²) on account of the dependency of the contact resistance between tungsten film 24 and polysilicon layer 22 on the nitrogen peak concentration in the oxide nitride film. The integrated value of the nitrogen concentration represents the number of nitrogen atoms that are present in a volume which is determined by the surface area 1 cm²×film thickness of the formed oxide nitride film.

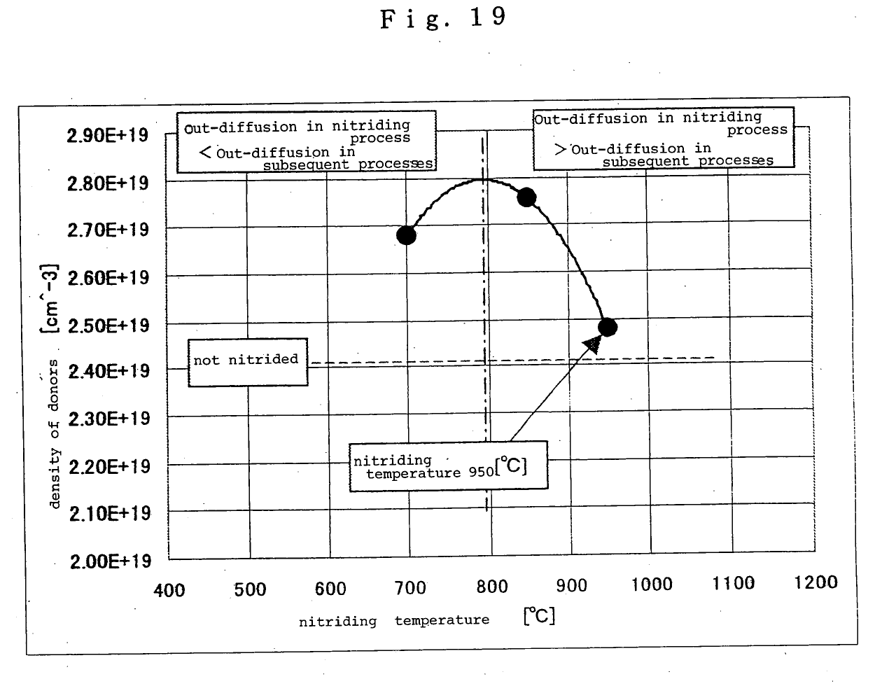

The nitriding conditions for gate side nitridation are limited by the outward diffusion based on the temperature of the nitriding process itself. It can be seen from FIG. 19 that an upper limit for the nitriding temperature is 1000° C. on account of the dependency of the donor concentration in polysilicon layer 22 near gate oxide film 21 on the nitriding temperature. If the nitriding temperature were higher than 1000° C., then the donor concentration would be lower than if no gate side nitridation were performed due to outward diffusion on nitridation, failing to achieve the advantages that are obtained if gate side nitridation is performed.

If the nitriding temperature is lower than about 800° C., then the diffused amount produced by the outward diffusion upon nitridation is smaller than the diffused amount produced by outward diffusion in subsequent processes. If the nitriding temperature is higher than about 800° C., then the diffused amount produced by the outward diffusion upon nitridation is greater than the diffused amount produced by outward diffusion in subsequent processes. Stated otherwise, if the nitriding temperature deviated largely from about 800° C., then either outward diffusion becomes too large, resulting in a reduction in the donor concentration. Accordingly, the donor concentration cannot be increased if the nitriding temperature is too high or too low. It can be seen from FIG. 19 that the nitriding temperature should be in the range from 700° C. to 950° C. in order to increase the donor concentration to obtain sufficient advantages compared with the process without any gate side nitridation.

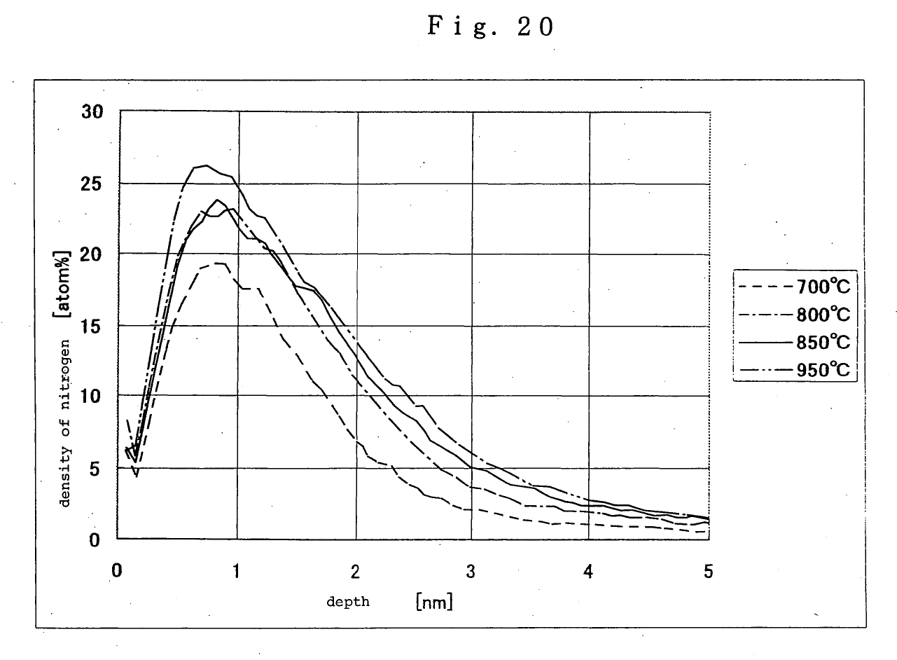

FIG. 20 shows the nitriding temperature dependency of the nitrogen concentration. In FIG. 20, [atom %] is defined by the number of nitrogen atoms in the number of all atoms in the thermal oxide film. The density of atoms in the thermal oxide film is 6×10²²/cm³.

2nd Embodiment:

A method of fabricating a semiconductor device according to a second embodiment of the present invention will be described below.

In the method of fabricating a semiconductor device according to the first embodiment as described above, after gate electrode 41 is formed and before the gate sides are subjected to side selective oxidization, the sides of gate electrode 41 are nitrided by RTA in the ammonia (NH₃) atmosphere. In the method of fabricating a semiconductor device according to the second embodiment, the sides of gate electrode 41 are nitrided by plasma nitridation, rather than RTA in the ammonia atmosphere. The plasma nitridation is performed at 400° C. under 500 mTorr with 1000 W.

The plasma nitridation is advantageous in that since nitrogen hardly reaches the surface of the silicon substrate, the oxidization of the silicon nitride is not suppressed, unlike in the ammonia atmosphere.

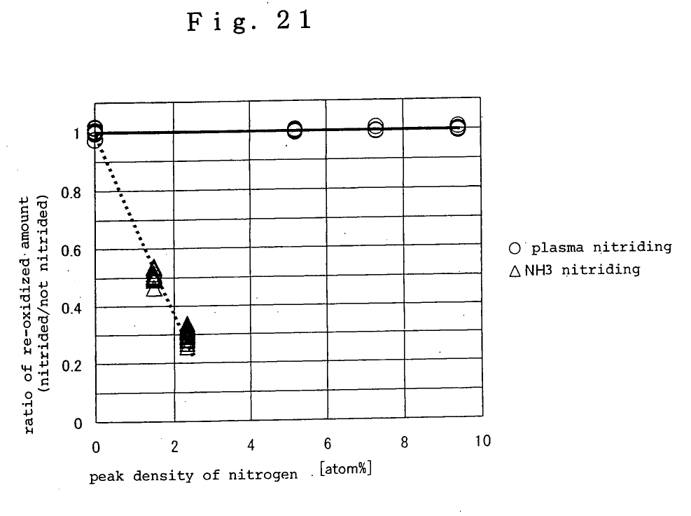

FIG. 21 shows the relationship between a ratio of re-oxidized amounts and a nitrogen peak concentration when gate side nitridation was performed by plasma nitridation according to the second embodiment and when gate side nitridation was performed by RTA in an ammonia atmosphere according to the first embodiment. In FIG. 21, the ratio of re-oxidized amounts represents a ratio of increases in the thickness of the oxide film in a subsequent oxidizing process when a wafer with an oxide film on its surface is nitrided and not nitrided, and is defined as (nitrided)/(not nitrided).

A study of FIG. 21 indicates that if gate side nitridation is performed by TRA in the ammonia atmosphere according to the first embodiment, oxidization is suppressed, and the ratio of re-oxidized amounts is smaller as the nitrogen peak concentration is greater, resulting in a reduction in the thickness of the oxide film in a subsequent oxidizing process, and that if plasma nitridation is performed according to the present embodiment, the ratio of re-oxidized amounts is substantially 1 even when the nitrogen peak concentration is higher, and will not affect the thickness of the oxide film in a subsequent oxidizing process. Therefore, the method of fabricating a semiconductor device according to the second embodiment is effective particularly if an under-gate birds beak is to be positively formed.

In the method of fabricating a semiconductor device according to the second embodiment, a lower limit for the amount of nitrogen (an integrated value of the nitrogen peak concentration or the nitrogen concentration) is determined in the same manner as if gate side nitridation is performed by RTA in an ammonia atmosphere. However, there is no upper limit depending on the temperature.

In the first and second embodiments of the present invention, the metal film serving as gate electrode 41 comprises tungsten film 24, and the tungsten nitride film is used as barrier film 23. However, the present invention is not limited to those details, but is also applicable to a semiconductor device having a gate electrode of polymetal structure made of other metals than tungsten.

While preferred embodiments of the present invention have been described using specific terms, such description is for illustrative purposes only, and it is to be understood that changes and variations may be made without departing from the spirit or scope of the following claims.

What is claimed is:

1. A method of fabricating a semiconductor device having a gate electrode of a polymetal gate structure which comprises a three-layer structure having a metal film, a barrier film, and a polysilicon layer, comprising the steps of:
successively forming a gate insulating film, a polysilicon layer, a barrier film, and a metal film on a semiconductor substrate;
etching said metal film, said barrier film, and said polysilicon layer to form a gate electrode;
effecting side nitridation on said gate electrode at a nitriding temperature ranging from 700° C. to 950° C. in an ammonia atmosphere; and
effecting side selective oxidization to oxidize said polysilicon layer and silicon in said semiconductor substrate without oxidizing said metal film.

2. A method of fabricating a semiconductor device having a gate electrode of a polymetal gate structure which comprises a three-layer structure having a metal film, a barrier film, and a polysilicon layer, comprising the steps of:
successively forming a gate insulating film, a polysilicon layer, a barrier film, and a metal film on a semiconductor substrate;
etching said metal film, said barrier film, and said polysilicon layer to form a gate electrode;
effecting side nitridation on said gate electrode by way of plasma nitridation; and
effecting side selective oxidization to oxidize said polysilicon layer and silicon in said semiconductor substrate without oxidizing said metal film.

3. A method according to claim 1, wherein said metal film comprises a tungsten film, and said barrier film comprises a tungsten nitride film.

4. A method according to claim 2, wherein said metal film comprises a tungsten film, and said barrier film comprises a tungsten nitride film.

5. A semiconductor device having a gate electrode of a polymetal gate structure which comprises a three-layer structure having a metal film, a barrier film, and a polysilicon layer, said polysilicon layer having sides nitrided with an integrated value of nitride concentration being at least 2×10¹⁵ atoms/cm².

6. A semiconductor device having a gate electrode of a polymetal gate structure which comprises a three-layer structure having a metal film, a barrier film, and a polysilicon layer, said polysilicon layer having sides nitrided with an integrated value of nitride concentration being at least 2×10¹⁵ atoms/cm², at a nitriding temperature ranging from 700° C. to 950° C. in an ammonia atmosphere.

7. A semiconductor device having a gate electrode of a polymetal gate structure which comprises a three-layer structure having a metal film, a barrier film, and a polysilicon layer, said polysilicon layer having sides nitrided by plasma nitridation with an integrated value of nitride concentration being at least 2×10¹⁵ atoms/cm².

8. A semiconductor device according to claim 5, wherein said metal film comprises a tungsten film, and said barrier film comprises a tungsten nitride film.

9. A semiconductor device according to claim 6, wherein said metal film comprises a tungsten film, and said barrier film comprises a tungsten nitride film.

10. A semiconductor device according to claim 7, wherein said metal film comprises a tungsten film, and said barrier film comprises a tungsten nitride film.
